(19) United States
(12) Patent Application Publication
(10) Pub. No.: US 2012/0314481 A1
(43) Pub. Date: Dec. 13, 2012

(54) CELL-STATE MEASUREMENT IN RESISTIVE MEMORY

(75) Inventors: Gael Close, Morges (CH); Christoph Hagleitner, Zurich (CH); Angeliki Pantazi, Zurich (CH); Nikolaos Papandreou, Zurich (CH); Charalampos Pozidis, Zurich (CH); Abu Sebastian, Zurich (CH)

(73) Assignee: International Business Machines Corporation, Armonk, NY (US)

(21) Appl. No.: 13/591,828

(22) Filed: Aug. 22, 2012

Related U.S. Application Data
(63) Continuation of application No. 13/415,127, filed on Mar. 8, 2012.

(30) Foreign Application Priority Data
Mar. 10, 2011 (EP) 11171144.6

(51) Int. Cl. G11C 11/00

(52) U.S. Cl. 365/148

(57) ABSTRACT

Apparatus and method for measuring the state of a resistive memory cell. A bias voltage controller applies a bias voltage to the cell and controls the level of the bias voltage. A feedback signal generator senses cell current due to the bias voltage and generates a feedback signal (S_{FB}) dependent on the difference between the cell current and a predetermined target current. The bias voltage controller controls the bias voltage level in dependence on the feedback signal (S_{FB}) such that the cell current converges on the target current. An output is provided indicative of the bias voltage level at which the cell current corresponds to the target current, thus providing a voltage-based metric for cell-state.

### CROSS REFERENCE TO RELATED APPLICATIONS

This application is a continuation of and claims priority from U.S. application Ser. No. 13/415,127 filed Mar. 8, 2012, which in turn claims priority under 35 U.S.C. §119 from European Patent Application No. 11157698.9 filed Mar. 10, 2011. Furthermore, this application is also related to the commonly owned U.S. patent application Ser. No. 13/415,061 and commonly owned U.S. patent application Ser. No. 13/415,012, both of which were filed concurrently with U.S. application Ser. No. 13/415,127 on Mar. 8, 2012. The entire contents of all of the aforementioned applications are incorporated herein by reference.

### BACKGROUND OF THE INVENTION

1. Field of the Invention

This invention relates generally to resistive memory and more particularly to apparatus and methods for measuring the state of resistive memory cells.

2. Description of Related Art

In resistive memory, the fundamental storage unit (referred to generally herein as the “cell”) can be set to a number of different states which exhibit different electrical resistance characteristics. Information is recorded by exploiting the different states to represent different data values. To read recorded data, cell-state is detected via measurements which exploit the differing resistance characteristics to differentiate between possible cell-states. A variety of semiconductor memory technologies employ these basic principles for data storage. Examples include oxide-based memory such as resistive RAM (random access memory) and memristor memory, ionic-transport-based memory, and phase-change memory. The following discussion will focus on phase-change memory (PCM) as a particularly promising technology for future non-volatile memory chips. It is to be understood, however, that PCM is only an illustrative application for the invention to be described which can be similarly applied to other resistive memory technologies.

Phase-change memory exploits the reversible switching of certain chalcogenide materials between at least two states with different electrical resistance. In so-called “single-level cell” (SLC) PCM devices, each cell be set to one of two states, crystalline and amorphous, by application of heat. Each SLC cell can thus store one bit of binary information. However, to satisfy market demand for ever-larger memory capacity, storage of more than one bit per cell is required. To achieve this, it is necessary that a cell can be set to s states where s>2, and that these states can be distinguished on readback via the cell resistance characteristics. Multi-level cell (MLC) operation has been proposed for PCM cells whereby each cell can be set to one of s>2 resistance levels, each corresponding to a different cell state. MLC operation is achieved by exploiting partially-amorphous states of the chalcogenide cell. Different cell states are set by varying the effective volume of the amorphous phase within the chalcogenide material. This in turn varies cell resistance.

To write data to a PCM cell, a voltage or current pulse is applied to the cell to heat the chalcogenide material to an appropriate temperature to induce the desired cell-state on cooling. By varying the amplitude of the voltage or current pulses, different cell-states can be achieved. Reading of PCM cells can be performed using cell resistance to distinguish the different cell-states. The resistance measurement for a read operation is performed in the sub-threshold region of the current-versus-voltage (I/V) characteristic of the cell, i.e. in the region below the threshold switching voltage at which a change in cell-state can occur. The read measurement can be performed in a variety of ways, but all techniques rely fundamentally on either voltage biasing and current sensing, or current biasing and voltage sensing. In a simple implementation of the current-sensing approach, the cell is biased at a certain constant voltage level and the resulting cell current is sensed to provide a current-based metric for cell-state. U.S. Pat. No. 7,426,134 B2 discloses one example of a current-sensing technique in which the bias voltage can be set to successively higher levels, and the resulting cell-current compared to successive reference levels, for detecting the different cell-states. US Patent Application Publication No. 2008/0025089 discloses a similar technique in which the cell current is simultaneously compared with different reference levels. In the alternative, voltage-sensing approach, a constant current is passed through the cell and the voltage developed across the cell is sensed to provide a voltage-based metric for cell-state.

Reading of MLC cells is particularly challenging as the read operation involves distinguishing fine differences in cell resistance via the current/voltage measurements. Compared to SLC operation, these fine differences are more readily affected by random noise fluctuations and drift over time, resulting in errors when retrieving stored data. To counteract this loss of data integrity associated with MLC memory, new cell-state metrics, beyond simple resistance, have been proposed. Our copending European Patent Application No. 10174613.9, filed 31 Aug. 2010, discloses a particularly promising metric which is based on the sub-threshold slope of the I/V characteristic of the cell. For example, the metric may be based on the difference between two read measurements of the same cell. This type of metric is less sensitive to noise and drift. In certain embodiments of this measurement technique, the metric is essentially a voltage-based metric in the sense that it calls for the measurement of cell voltages (or cell voltage differences) at given bias currents. In general, voltage-based metrics are considered advantageous over current-based metrics, showing less drift over time, less susceptibility to noise, better SNR (signal-to-noise ratio), and allowing more intermediate levels to be packed into one cell. However, the conventional technique for obtaining voltage-based metrics, using current biasing and voltage sensing, is undesirably slow as explained above. This speed penalty associated with the conventional voltage measurement technique means that there is a fundamental conflict between the requirement for a fast random access of the memory and the need for voltage-based metrics supporting high density MLC memory.

### SUMMARY OF THE INVENTION

In accordance with one aspect of the present invention apparatus is provided for measuring the state of a resistive memory cell. The apparatus includes: a bias voltage controller for applying a bias voltage to the cell and controlling the level of the bias voltage; and a feedback signal generator for sensing cell current and generating a feedback signal (S_{FB}) dependent on the difference between the cell current and a predetermined target current. The bias voltage controller is adapted to control the bias voltage level in dependence on the feedback signal (S_{FB}) so that the cell current converges on the target current, and provides an output indicative of the bias voltage level at which the cell current corresponds to the target current.

In accordance with another aspect of the present invention, a memory device includes: a plurality of resistive memory cells; and read/write apparatus for reading and writing data in the memory cells. The read/write apparatus includes apparatus as set forth above for measuring the state of a memory cell.

In accordance with a further aspect of the invention, a method for measuring the state of a memory cell includes the steps of: applying a bias voltage to the cell; sensing cell current due to the bias voltage; controlling the bias voltage level in dependence on the difference between the cell current and a predetermined target current so that the cell current converges on the target current; and providing an output indicative of the bias voltage level at which the cell current corresponds to the target current.

Where features are described herein with reference to an embodiment of one aspect of the invention, corresponding features may be provided in embodiments of another aspect of the invention.

### BRIEF DESCRIPTION OF THE DRAWINGS

Preferred embodiments of the invention will be described, by way of example, with reference to the accompanying drawings in which:

FIG. 1 is a schematic block diagram of a memory device embodying the invention;

FIG. 2 is a schematic block diagram of measurement apparatus of the memory device;

FIG. 3 shows an exemplary implementation for a feedback signal generator of the FIG. 2 apparatus;

FIG. 4 illustrates simulated I/V characteristics for different resistance levels of a PCM cell;

FIG. 5 indicates steps of a measurement operation performed by the FIG. 2 apparatus;

FIG. 6 is a timing diagram for signals involved in the measurement operation; and

FIG. 7 indicates measurements for deriving cell-state metrics in further embodiments of the invention.

### DETAILED DESCRIPTION OF THE PREFERRED EMBODIMENTS

Measurement apparatus embodying this invention provides a voltage-based metric via a technique based on voltage biasing and current sensing. By avoiding constant-current biasing as in the conventional approach, the speed penalty associated with that approach can be avoided. Embodiments of the invention thus offer the benefits of voltage-based metrics without the performance penalty of the prior voltage-measurement technique. Moreover, the measurement apparatus can be embodied in simple, highly efficient circuit implementations as discussed further below.

In general, the output of the bias voltage controller may indicate bias voltage level directly, e.g. as the voltage value itself, or indirectly in terms of any convenient parameter related to bias voltage level. This output may be used to determine cell-state in any convenient manner, either directly as a cell-state metric in its own right, or after further processing to obtain the final cell-state metric. In a particularly advantageous implementation, the bias voltage controller includes a voltage generator including control logic for generating a digital code indicative of the bias voltage level, and a digital-to-analog converter for converting the digital code into an analog control voltage. The bias voltage applied to the cell is dependent on this control voltage. The bias voltage here could be the control voltage itself or the control voltage may be further processed to produce the bias voltage applied to the cell. In any case, the bias voltage level is related via the control voltage to the digital code produced by the control logic, whereby the digital code ultimately determines bias voltage level. In this case, the measurement output of the bias voltage controller can simply be the digital code at which the cell current corresponds to the target current. This highly efficient implementation effectively provides a built-in ADC (analog-to-digital converter) in the measurement circuit architecture, obviating the additional ADC required in conventional voltage-metric circuits in order to provide a digital output.

While embodiments might be envisaged for use with two-level memory cells, application to multilevel cells is especially advantageous. When applied for measuring the state of an s-state memory cell where s>2, the digital code may be selectively representative of s values corresponding to respective cell states. Hence, the control logic can set the code to one of s values each of which corresponds to a different cell state and results in one of s different bias voltage levels being applied to the cell. The code value for the bias voltage level at which cell current corresponds to the target current then provides a direct indication of cell state.

According to further embodiments, voltage regulation techniques can be employed to drive the cell bit-line quickly to the various bias voltage levels, thus increasing operating speed and further enhancing performance. In preferred embodiments, therefore, the bias voltage controller includes, in addition to a voltage generator for generating a control voltage, a voltage regulator for controlling the bias voltage applied to the cell in dependence on the control voltage. The nature of this control may vary and need not be strict 1:1 regulation, the key point being that the regulator operates such that a change in the control voltage produces a related change in the bias voltage whereby the bias voltage level can be controlled by changing the control voltage.

The feedback signal generator is sensitive to the current flowing through the cell due to the applied bias voltage and generates a feedback signal dependent on the difference between this cell current and a predetermined target current. The feedback signal generator can be conveniently implemented by a simple comparator circuit. In general, the feedback signal generator may sense cell current directly, by sensing current per se, or indirectly via any convenient parameter indicative of cell current which can then be compared with a corresponding parameter indicative of the target current. The resulting feedback signal may depend in various ways on the difference between the cell current and target current. In a particularly simple implementation, the feedback signal may simply depend on whether or not the cell current is greater than (or less than) the target current. In this case, the feedback signal generator can be efficiently implemented by a current detector and a 1-bit comparator as described further below.

The feedback signal is used by the bias voltage controller in controlling the bias voltage level. Specifically, the bias voltage level is controlled in dependence on the feedback signal such that the cell current converges on the target current. The bias voltage controller may be adapted to control the bias voltage level in accordance with a successive approximation technique, for instance a binary search technique. As the bias voltage level changes, the cell current changes accordingly, moving towards the target current. The adjustment continues until the cell current corresponds to the target current, the bias voltage level at this point determining the output of the apparatus. The degree of correspondence here will depend on the desired accuracy, but the cell current will typically be substantially equal to the target current, i.e. will lie within a known error margin of the target, this margin being sufficiently small that the output reliably indicates a single cell-state.

In some embodiments, cell-state may be determined based on a single measurement output. In others, a plurality of measurements may be made to determine cell-state. In particular, the apparatus may include a measurement controller for controlling the bias voltage controller and feedback signal generator such that the bias voltage controller provides an output for each of a plurality of predetermined target currents. The measurement controller then determines the state of the cell in dependence on the plurality of outputs. By way of example, a difference metric of the type described in our aforementioned European Patent Application No. 10174613.9 can be obtained by performing at least two measurements to obtain measurement outputs at different target currents, the measurement controller then determining cell-state from the difference between values dependent on respective measurement outputs. Such embodiments allow a difference metric, or even more complex non-linear metrics, to be obtained via simple circuit implementations using only linear analog components.

FIG. 1 is a simplified schematic of a resistive memory device embodying the invention. The device 1 includes phase-change memory 2 for storing data in one or more integrated arrays of multilevel PCM cells. Though shown as a single block in the figure, in general memory 2 may include any desired configuration of PCM storage units ranging, for example, from a single chip or die to a plurality of storage banks each containing multiple packages of storage chips. Reading and writing of data to memory 2 is performed by read/write apparatus 3. Apparatus 3 includes data-write and read-measurement circuitry 4 for writing data to the PCM cells and for making cell measurements allowing determination of cell-state and hence readback of stored data. Circuitry 4 can address individual PCM cells for write and read purposes by applying appropriate voltage signals to an array of word and bit lines in memory ensemble 2. This process is performed in generally known manner except as detailed hereinafter. A read/write controller 5 controls operation of apparatus 3 generally and in particular controls measurement operations in the embodiments to be described, as well as processing of measurements for determining cell-state, i.e. level detection, where required. In general, the functionality of controller 5 can be implemented in hardware or software or a combination thereof, though use of hardwired logic circuits is generally preferred for reasons of operating speed. Suitable implementations will be apparent to those skilled in the art from the description herein. As indicated by block 6 in the figure, user data input to device 1 is typically subjected to some form of write-processing, such as coding for error-correction purposes, before being supplied as write data to read/write apparatus 3. Similarly, readback data output by apparatus 3 is generally processed by a read-processing module 7, e.g. performing codeword detection and error correction operations, to recover the original input user data. Such processing by modules 6 and 7 is independent of the cell-state measurement system to be described and need not be discussed further here.

Each of the multilevel cells in memory 2 can be set to one of s resistance levels, where s>2, corresponding to different amorphous/crystalline states of the cell. To write data to memory cells, circuitry 4 applies programming pulses (via cell bit-lines or word-lines depending on whether voltage-mode or current-mode programming is used) of appropriate amplitude to set cells to states representative of the write data. Subsequent reading of a memory cell involves determining the state of the cell, i.e. detecting which of the possible levels that cell is set to. In a read operation of memory device 1, circuitry 4 performs cell measurements from which cell-states can be determined and the stored data recovered.

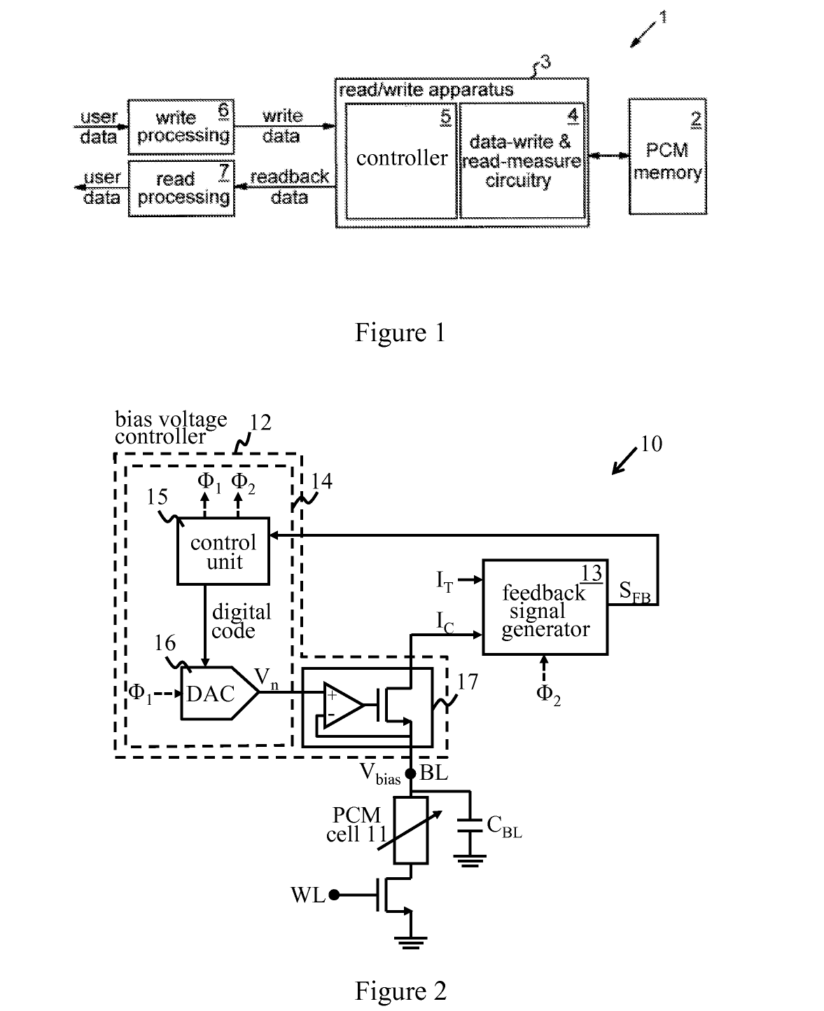

FIG. 2 shows one embodiment of measurement apparatus for use in circuitry 4 of the memory device 1. The measurement apparatus 10 is shown connected to a PCM cell 11, represented as a variable resistance in the figure, for a measurement operation. A particular cell is accessed for this operation via voltages applied to the appropriate word-line WL and bit-line BL for that cell. The measurement apparatus 10 includes a bias voltage controller, indicated generally at 12, for applying a bias voltage V_{bias} to the cell bit-line BL. The apparatus 10 further includes a feedback signal generator 13 for generating a feedback signal S_{FB} which is fed-back to bias voltage controller 12. The bias voltage controller 12 includes a voltage generator, indicated generally at 14, including a control unit 15 and a digital-to-analog converter (DAC) 16 for generating a control voltage Vₙ. The control unit 15 includes control logic for generating a digital code for output to DAC 16 as well as timing signals φ₁, φ₂ described further below. Voltage controller 12 further includes a voltage regulator 17 for controlling the bias voltage V_{bias} in dependence on the control voltage Vₙ from DAC 16.

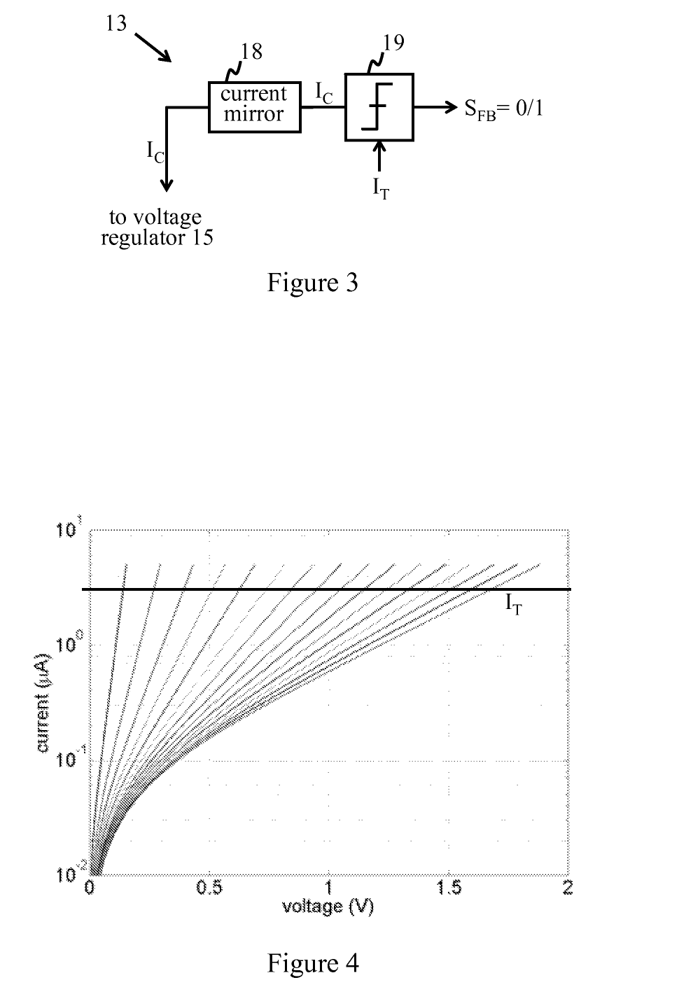

FIG. 3 shows an exemplary implementation of feedback signal generator 13 employed in this embodiment. The feedback signal generator consists here of a current detector, in the form of current mirror 18, and a 1-bit comparator 19 for producing the feedback signal S_{FB}. In general, however, the various circuit components in measurement apparatus 10 may be implemented in any convenient manner, and various suitable implementations will be readily apparent to those skilled in the art from the description of operation herein.

A measurement operation by apparatus 10 is initiated when required by controller 5 of read/write apparatus 3 in FIG. 1. In operation, control unit 15 generates a digital code indicative of an initial bias voltage level to be applied at bit-line BL of the cell 11 to be read. This digital code is output to DAC 16 and converted thereby into analog control voltage Vₙ. The control voltage Vₙ is supplied to voltage regulator 17. In this preferred embodiment, voltage regulator 17 is selected to perform fast voltage regulation of the bit-line voltage on a 1:1 basis with Vₙ. In particular, the fast voltage regulator 17 can pull the bit-line voltage quickly (e.g. in about 30 ns) up to Vₙ, thus quickly countering the effect of the parasitic bit-line capacitance which is indicated by C_{BL} in FIG. 2. The current flowing through cell 11 thus settles quickly to that corresponding to the applied bias voltage V_{bias}, where V_{bias}=Vₙ in this example. The resulting cell current I_{C} due to V_{bias} is sensed by feedback signal generator 13. This generates feedback signal S_{FB} in dependence on the difference between the cell current I_{C} and a predetermined target current I_{T}. In particular, in this embodiment the cell current I_{C} is detected by current mirror 18 and supplied to a first input of comparator 19. The target current I_{T} is supplied (e.g. by control unit 15 or read/write controller 5) to a second input of comparator 19. The comparator 19 generates a 1-bit output S_{FB} according to whether or not I_{C} exceeds the target current I_{T}.

The feedback signal S_{FB} is fed back to the control unit 15 of bias voltage controller 12. The control unit 15 adjusts the digital code supplied to DAC 16 depending on the value of feedback signal S_{FB}. This in turn alters control voltage Vₙ driving voltage regulator 17, thereby changing the bias voltage V_{bias}. By adjusting the digital code based on S_{FB} in this way, control unit 15 can control the bias voltage level such that the cell current I_{C} converges on the target current I_{T}. This control process is described in more detail below. When convergence is achieved, i.e. when V_{bias} has been adjusted such that I_{C} corresponds to the target I_{T}, the current value of the digital code provides the result of the measurement operation. The digital code is thus output to read/write controller 5 for recovering stored data.

It will be seen from the above that the digital code from control unit 15 is directly indicative of the bias voltage level applied to cell 11. By means of this digital code, the closed-loop arrangement involving fast voltage-biasing, current sensing and comparison is regulated by controller 12 to achieve convergence with a target current. In this way, the apparatus 10 allows a voltage-based metric for cell state to be extracted directly in digital form.

The control process performed by control unit 15 will now be described in more detail with reference to FIGS. 4 to 6. In this example, the bias voltage control loop is regulated by control unit 15 in accordance with a successive approximation technique. This operation is described in the following for an exemplary read-measurement of a 16-level PCM cell. FIG. 4 shows simulated I/V characteristics for the sixteen levels (cell-states) of such a cell based on measurement data obtained from PCM cells. The horizontal line indicates an exemplary target current I_{T} for the read measurement. It can be seen that, for each state, the target current is obtained at a different bias voltage level. The object of the measurement operation by apparatus 10 is to determine the particular bias voltage level at which the cell current I_{C} corresponds to the target current I_{T} with sufficient accuracy to identify a particular one of the sixteen possible cell-states.

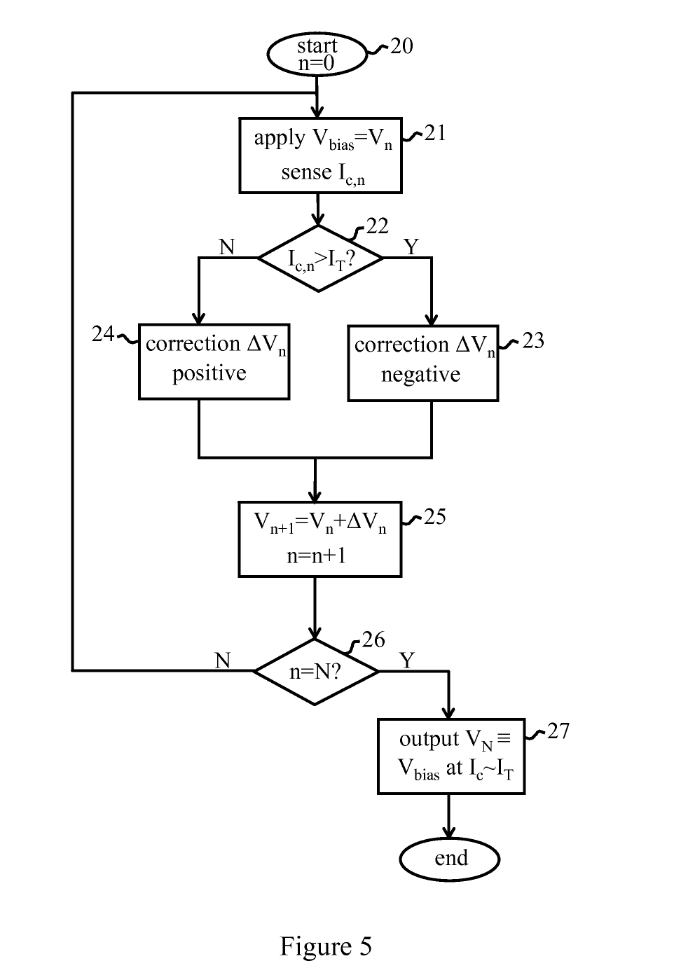

The flow chart of FIG. 5 indicates key steps of the iterative measurement operation. The operation commences at step 20 with a cycle count n initiated to n=0. In step 21, the digital code value is set by control unit 10 to generate a first control voltage V₀ which is applied to the cell as the bias voltage V_{bias}=V₀. The resulting cell current I_{C,0} is sensed by current mirror 18 and compared with the target current I_{T} by comparator 19 as already described. If I_{C,0}>I_{T}, as indicated by a “yes” (Y) at decision step 22, the cell bias voltage needs to be reduced. In this case, comparator 19 sets S_{FB}=1 and the control unit 15 adjusts the digital code to make a negative correction ΔV₀ to the initial control voltage V₀. This is indicated by step 23 of FIG. 5. Conversely, if I_{C,0}>I_{T} as indicated by a “no” (N) at decision step 22, then comparator 19 sets S_{FB}=0 and control unit 15 adjusts the digital code to make a positive correction ΔV₀ to the control voltage as indicated by step 24 of the figure. The precise nature of correction ΔV in steps 23 and 24 depends on the particular successive approximation technique employed, the key point being that the cell voltage for the next iteration is calculated as V₁=V₀+ΔV₀ as indicated at step 25, the control unit 15 adjusting the digital code output to DAC 16 as required to achieve this. The cycle counter n is then incremented for the next iteration. In decision step 26 control unit 15 checks if the cycle count n has reached a predefined count value N, commensurate with the required accuracy, indicating that sufficient iterations have been performed to determine cell state. If not, then operation reverts to step 21, applying the adjusted bias voltage V_{bias}=V₀ for the next cycle. The process thus iterates until the required number of cycles have been performed at step 26, whereupon the search loop terminates. At this point (Y at decision block 26), the final bias voltage V_{bias}=V_{N} (and the corresponding digital code) is such that cell current equals the target current within the desired accuracy. The final bias voltage V_{N}, indicated by its equivalent digital code value, is then output at step 27 and the measurement operation is complete.

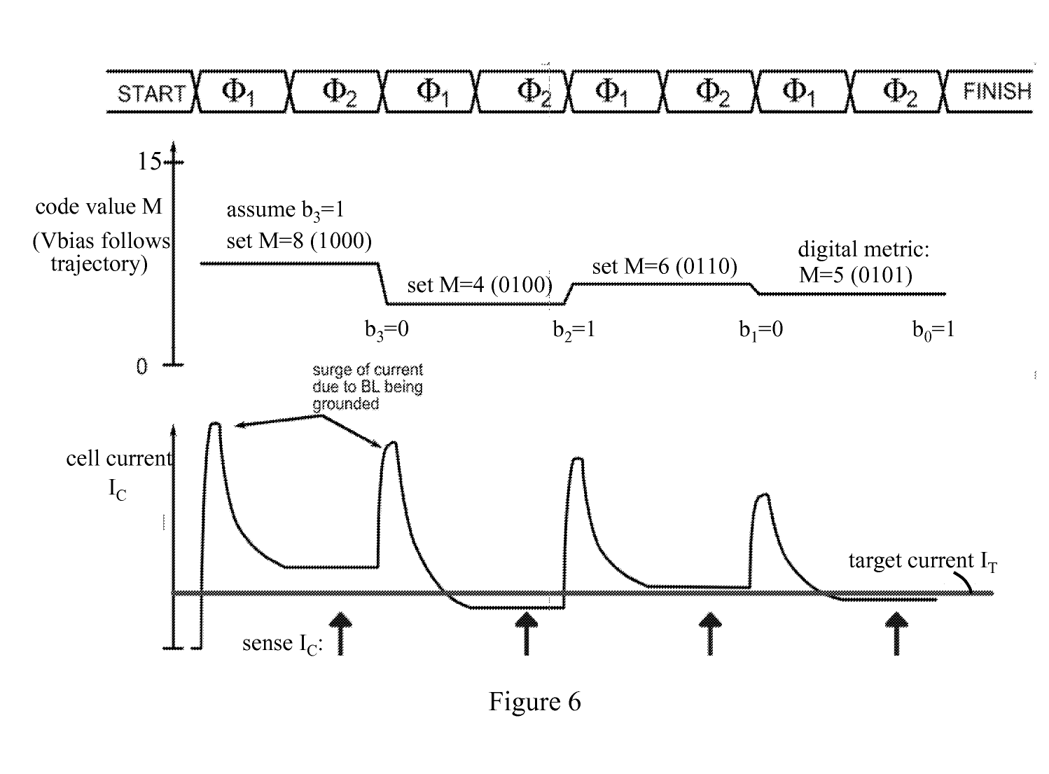

A particular example of the basic control process described above is illustrated in the timing diagram of FIG. 6. In this example, the control unit 15 implements a binary search technique via the control loop. The upper section of FIG. 6 shows the timing signals φ₁, φ₂ generated by control unit 15 to control the operating cycles. The middle section shows how the digital code value (and hence bias voltage level) changes through the measurement operation. The lower section indicates how cell current I_{C} varies in relation to the target current I_{T} over successive operating cycles.

Each cycle of the iterative measurement process consists of two phases defined by timing signals φ₁ and φ₂. In the first phase when φ₁ is high, a new bias voltage level is set via the digital code from control unit 15, and the cell current is allowed to settle. In the second phase when φ₂ is high, the cell current I_{C} is sensed (as indicated by the arrows in the figure) and compared with the target to generated the feedback signal S_{FB}. In the present example, assuming 16-level memory cells, the digital code can be selectively set by control unit 15 to one 16 values each corresponding to a respective cell state. Hence, via operation of bias voltage controller 12, each code value produces a particular bias voltage level at the cell bit-line to generate a cell current corresponding to the target current for a respective one of the sixteen possible cell states. The sixteen code values are indicated in the figure by values M=0 to 15. These values are represented by a 4-bit binary code output by control unit 15, the four bits being denoted by b₃, b₂, b₁ and b₀ in the figure.

FIG. 6 illustrates operation of the measurement apparatus for an assumed cell-state M_{cell} corresponding to M=5. In the first cycle of the process, the initial code value is set to M=8 whereby binary code 1000 is output by control until 15. In response to timing signal φ₁ the cell bit-line is momentarily grounded, resulting in the surge of cell current indicated at the start of the current trace in the figure, and the DAC 16 outputs control voltage Vₙ to voltage regulator 17. Once the current has settled and φ₂ goes high, the cell current is sensed by feedback signal generator 13. Since the initial bias voltage corresponds to M=8 whereas the actual cell state corresponds to M=5, the cell current will be higher than the target as indicated for this cycle, and the control unit will receive a feedback signal S_{FB}=1. This indicates that b₃=0 for the current cell-state, i.e. M_{cell}=(0, b₂, b₁, b₀), and a negative correction to V_{bias} is required.

In accordance with the binary search procedure, the code value for the second cycle is set to M=4, whereby binary code 0100 is output by control unit 15. The cell bit-line BL is pulled low at the start of the cycle as before. In the measurement phase of this cycle, the cell current will be lower than the target as indicated since the current code value M=4 is lower than the actual cell-state M_{cell}=5. For this cycle, therefore, the control unit will receive a feedback signal S_{FB}=0. This indicates that b₂=1 for the current cell-state, i.e. M_{cell}=(0, 1, b₁, b₀), and a positive correction to Vbias is now required.

In the third cycle the code value is set to M=6, whereby binary code 0110 is output by control unit 15. In the measurement phase of this cycle, the cell current will be higher than the target as indicated, and control unit 15 will receive a feedback signal S_{FB}=1. This indicates that b₁=0 for the current cell-state, i.e. M_{cell}=(0, 1, 0, b₀), and a negative correction to Vbias is required. The code value is then decreased to M=5 for the final cycle, whereupon the cell current corresponds to the target I_{T} and the final digital code 0101 provides a direct digital metric for the cell-state M_{cell}=5. (Note that this final cycle is required to eliminate the possibility that M_{cell}=4 since the single 1-bit comparator in this example indicates only whether the cell current is greater than the target, and so does not distinguish (in the second cycle above) between cell currents lower than or equal to the target. The control process here therefore operates for N cycles where 2″ equals the number of possible cell states. Hence, the process iterates for N=4 cycles in this illustration. Note also that, in relation to the generalized flow chart of FIG. 5, the final correction to the code value corresponding to step 23 or 24 is only made as far as this is possible within the granularity of possible code values. Hence no positive correction, corresponding to step 24 of FIG. 5, is made for the M=5 code value set for the final cycle of FIG. 6.)

It will be seen that the above embodiment provides a simple and efficient apparatus for direct extraction of a voltage based cell-state metric via a voltage biasing technique. Compared to the conventional approach of direct current-biasing and voltage-sensing, the search loop is significantly faster despite the number of iterations required. Considering a typical example where the memory cell exhibits a resistance of around 1 MOhm and is part of a large array where the bit-line capacitance is 1 pF, conventional direct current-biasing with a typical read current of 1 μA would take 1 μS just for the cell voltage to settle. By contrast, the voltage search loop described above could converge in 320 ns, assuming each iteration takes about 40 ns (with a fast voltage regulator in 90 nm CMOS), and that 8 iterations are needed (for example in the case of a binary search with an 8-bit accuracy). The above-described scheme therefore yields a significant speed advantage, resolving the prior conflict between the need for high-speed operation and the use of voltage-based metrics. Another advantage is that the digital code representing the analog voltage-based metric arises naturally at the output of the search-loop control unit. The analog-to-digital conversion is thus built-in directly within the loop, avoiding the need for the ADC required in the conventional approach.

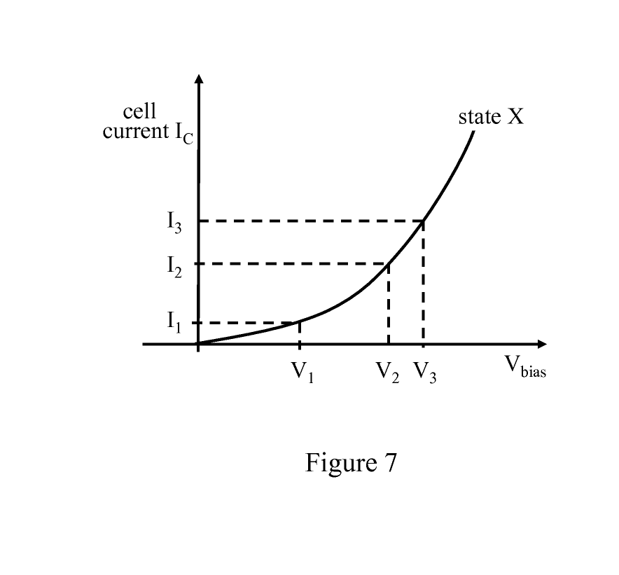

While the above system provides a single measurement as a direct metric for cell-state, measurements made in other embodiments may be processed in some manner to obtain the final metric for cell-state. For example, read/write controller 5 could control the measurement operation such that a plurality of measurements is made on a single cell for a read operation. In particular, under control of controller 5, the measurement operation could be performed for each of a plurality of different target currents, with the resulting set of measurements being processed in controller 5 to derive the cell-state metric. FIG. 7 illustrates the fundamental idea here whereby measurement outputs corresponding to bias voltages V₁, V₂, V₃, . . . are obtained from respective target currents I₁, I₂, I₃, . . . , providing additional information about the state X of the cell and allowing level discrimination via more sophisticated cell-state metrics. As a particular example, we consider a “difference metric” of the type discussed in our aforementioned European Patent Application No. 10174613.9. This metric M₂ corresponds to the inverse of the sub-threshold slope of the I/V characteristic of the cell:

$${M}_{2} = \frac{< V}{< ln ( I )} = \frac{{V}_{2} - {V}_{1}}{ln ( {I}_{2} / {I}_{1} )}$$

The above measurement operation can be repeated with another target current I_{T2}=KI_{T1}, where K is known, e.g. K=2, and can easily be generated from Iₙ using a current mirror. The difference metric (or a scaled version) can then be calculated in controller 5 as V₂−V₁:

$${M}_{2} = \frac{{V}_{2} - {V}_{1}}{ln ( K )} \} {V}_{2} - {V}_{1}$$

In this way, a digital measure of the metric M₂ is obtained by a straightforward difference of the two digital codes obtained at the end of the two search-loop runs. With this system, a highly non-linear metric such as M₂ can be obtained quickly with only linear analog components and a digital subtraction. Many other variants can be envisaged. For instance multiple measurements can be made and the differences between several pairs of these measurements could be used (e.g. averaged) to obtain another difference metric. In general, a broad family of metrics, which can exploit further the full I/V curve of the cell, could be obtained:

M_{X}=f(Vₖ,Vₖ₋₁, . . . V₁),

where each bias voltage measurement Vₖ corresponds to a certain target current Iₖ and in general:

Iₖ=g(Iₖ₋₁, . . . I₁),

where f and g represent known functions. Such metrics based on plural measurement operations can offer improved robustness to noise and drift. The simple circuit architecture described thus offers faster MLC memory (e.g. by a speed factor of about 3 to 5) based on drift-robust information storage in a variety of voltage-based metrics.

Numerous changes and modifications can of course be made to the exemplary embodiments described above. Various other successive approximation schemes, for instance, could be employed in the control loop. Such schemes are well known, e.g. for use in successive approximation ADCs. Various known techniques may also be employed to speed up the search loop if desired. For example, a single 1-bit comparator is employed in the simple architecture above whereby the feedback signal depends only on whether or not cell current exceeds the target. In other embodiments, the difference between the cell current and target current could be further quantified by the feedback signal generator, e.g. through use of additional comparators, allowing faster convergence on the target. The voltage regulation could also be modified of course, e.g. to enforce a relation other than a 1:1 ratio between the control voltage and the bias voltage. Also, the cell bit-line is pulled low between search-loop cycles above because the simple regulator of FIG. 2 is only fast at pulling the bit-line up. More complex devices could be employed if desired to provide bi-directional voltage regulation. Various other techniques might also be employed for generating the bias voltage applied to the cell.

Although the measurement operation is described above in the context of a read operation, cell-state measurement could also be performed during write operations. For example, our copending European Patent Application No.
11157709.4, filed 10 Mar. 2011, describes techniques for programming memory cells in dependence on cell-state measurements made during the write cycle. For example, the amplitude of the programming signal used to set the cell to a desired state can be determined based on the measured cell-state metric. Measurement techniques embodying this invention could be similarly employed during memory write operations.

Although the measurement system is described above with specific reference to PCM cells, embodiments of the invention can be similarly applied to other resistive memory technologies such as resistive RAM, memristor and ionic-transport-based memories.

It will be appreciated that many other changes can be made to the exemplary embodiments described without departing from the scope of the invention.

1. Apparatus for measuring the state of a resistive memory cell, the apparatus comprising:
a bias voltage controller for applying a bias voltage to the cell and controlling the level of the bias voltage; and
a feedback signal generator for sensing cell current and generating a feedback signal (S_{FB}) dependent on the difference between the cell current and a predetermined target current;
wherein the bias voltage controller is adapted to control the bias voltage level in dependence on the feedback signal (S_{FB}) such that the cell current converges on said target current, and to provide an output indicative of the bias voltage level at which the cell current corresponds to the target current.

2. Apparatus as claimed in claim 1 wherein the bias voltage controller comprises a voltage generator comprising:
control logic for generating a digital code indicative of the bias voltage level; and
a digital-to-analog converter for converting the digital code into an analog control voltage;
wherein the bias voltage applied to the cell is dependent on said control voltage.

3. Apparatus as claimed in claim 1 wherein the bias voltage controller comprises a voltage generator for generating a control voltage and a voltage regulator for controlling the bias voltage applied to the cell in dependence on the control voltage.

4. Apparatus as claimed in claim 3 wherein the voltage generator comprises:
control logic for generating a digital code indicative of the bias voltage level; and
a digital-to-analog converter for converting the digital code into said control voltage.

5. Apparatus as claimed in claim 2 wherein said digital code is selectively representative of s values corresponding to s respective cell states, said apparatus being used for measuring the state of an s-state resistive memory cell where s>2.

6. Apparatus as claimed in claim 5 wherein the bias voltage controller is adapted to control the bias voltage level in accordance with a successive approximation technique.

7. Apparatus as claimed in claim 6 wherein the bias voltage controller is adapted to control the bias voltage level in accordance with a binary search technique.

8. Apparatus as claimed in claim 7 wherein the feedback signal generator comprises a current detector for detecting the cell current and a comparator for comparing the detected cell current with said target current.

9. Apparatus as claimed in claim 8 including a measurement controller for controlling the bias voltage controller and feedback signal generator such that the bias voltage controller provides a said output for each of a plurality of predetermined target currents, the measurement controller being adapted to determine the state of the cell in dependence on said plurality of outputs.

10. Apparatus as claimed in claim 9 wherein the measurement controller is adapted to determine the state of the cell in dependence on the difference between values dependent on respective said outputs.

11. A memory device comprising:
memory comprising a plurality of resistive memory cells; and
read/write apparatus for reading and writing data in the memory cells, wherein the read/write apparatus includes apparatus measuring the state of a said memory cell, said apparatus for measuring comprising
a bias voltage controller for applying a bias voltage to the cell and controlling the level of the bias voltage; and
a feedback signal generator for sensing cell current and generating a feedback signal (S_{FB}) dependent on the difference between the cell current and a predetermined target current;
wherein the bias voltage controller is adapted to control the bias voltage level in dependence on the feedback signal (S_{FB}) such that the cell current converges on said target current, and to provide an output indicative of the bias voltage level at which the cell current corresponds to the target current.

12. A memory device as claimed in claim 11 wherein the memory comprises a plurality of s-state memory cells where s>2.

13. A memory device as claimed in claim 11 wherein the memory comprises a plurality of phase-change memory cells.
